(19) United States
(12) Patent Application Publication
(10) Pub. No.: US 2010/0307592 A1
(43) Pub. Date: Dec. 9, 2010

(54) Three-dimensional indium-tin-oxide electrode, method of fabricating the same, device of fabricating the same, and method of fabricating solar cell comprising the same

(75) Inventors: Chia-Hua Chang, Shulin City (TW); Pei-Chen Yu, Hsinchu City (TW); Min-Hsiang Hsu, Banqiao City (TW); Kung-Hwa Wei, Hsinchu City (TW); Ming-Shin Su, Luzhu Township (TW)

Correspondence Address: BACON & THOMAS, PLLC, 625 SLATERS LANE, FOURTH FLOOR, ALEXANDRIA, VA, 22314-1176, US

(73) Assignee: National Chiao Tung University, Hsinchu City (TW)

(21) Appl. No.: 12/585,641

(22) Filed: Sep. 21, 2009

(30) Foreign Application Priority Data
Jun. 8, 2009 (TW) 098119016

(51) Int. Cl. H01L 31/0224; H01L 21/28; H01B 5/00; B05D 5/12; C23C 16/00

(52) U.S. Cl. 136/263; 438/82; 174/128.1; 427/78; 118/728; 257/E21.158; 977/773

(57) ABSTRACT

A three-dimensional ITO electrode and the method of fabricating the same are disclosed. The three-dimensional ITO electrode of the present invention has a conductive layer and a plurality of ITO nanorods formed on the conductive layer, wherein the length range of the ITO nanorods can vary from 10 nm to 1500 nm. The best length is about 50 nm-200 nm for organic solar cells. When applied into organic optoelectronic devices such as organic solar cells and organic light-emitting diodes (OLEDs), the three-dimensional structure of the ITO electrode may increase the contact area to the active layer, thus improving the electric current collecting efficiency and uniformity of current spreading (flowing). Also, an evaporator, a solar cell comprising the above three-dimensional ITO electrode, and the method of fabricating the solar cell are disclosed.

### BACKGROUND OF THE INVENTION

1. Field of the Invention

The present invention relates to a three-dimensional ITO (indium-tin oxide) electrode, the method of fabricating the same, an evaporator for fabricating the same, a solar cell comprising the same, and the method of fabricating the said solar cell.

2. Description of Related Art

Referenced with FIG. 1, the process steps for fabricating a conventional solar cell are disclosed. First, a transparent ITO electrode layer 11 is formed on a glass substrate 10 (S1), followed by spin-coating a hole-transporting layer (HTL) 12 being spun-coated on the ITO electrode layer 11 (S2) and then an organic active layer 13 is formed on the hole-transporting layer (HTL) 12 (S3). Finally, an aluminum electrode 14 is formed on the organic active layer 13 (S4). Therefore a conventional solar cell having an ITO electrode layer 11, a hole-transporting layer (HTL) 12, an organic active layer 13, and an aluminum electrode 14 is provided.

However, it is difficult to form efficient metal contacts between the organic active layer and the ITO electrode layer due to the low stability (low resistance to acid or base) of the material of the organic active layer and the limited layered structure (two-dimensional structure) of the two electrodes, the ITO electrode 11 and the aluminum electrode 14. Hence, there has been significant difficulty to improve the efficiency of the solar cell.

Recently, Jason et al. proposed a ZnO nanowire-based dye-sensitized solar cell structure comprising ZnO nanowires acting as the electrode of the cell, in which such ZnO nanowires having a branched structure were formed by the MOCVD (Metalorganic Chemical Vapor Deposition) method (Jason B. Baxter and Eray S. Aydil, Appl. Phys. Lett. 86, 053114(2005)). The branched structure of the ZnO nanowires provides a larger contact area to the dye molecules in order to increase electrical current paths. However, the performance achieved less success than expected. Since ZnO is an unstable material that may be easily eroded by acid or base and is of high sheet resistance, and moreover, having merely 80% of transmittance via visible light, it is extremely limited in improving the electric efficiency of the solar cell. Meanwhile, as high equipment costs for MOCVD methods are incurred and excessive time is consumed for growing ZnO nanowires, difficulties exist for large quantities to be manufactured therefore the industrial application of such method cannot be realized.

Accordingly, there is a present need to develop an electrode with high stability (high resistance to acid or base), low electric resistance, high transmittance to visible light, which enables the cost of fabricating organic optoelectronic devices with high efficiency to be lowered and simultaneously enables the process time to be reduced.

### SUMMARY OF THE INVENTION

The three-dimensional ITO electrode of the present invention comprises a conductive layer and a plurality of ITO nanorods formed on the conductive layer. The adjustable length of the ITO nanorods ranges from 10 nm to 1500 nm, the adjustable diameter of the ITO nanorods ranges from 10 nm to 120 nm, and the adjustable distribution density of the ITO nanorods formed on the conductive layer ranges from 1×10⁶ to 5×10¹⁰ per cm². The three-dimensional ITO electrode of the present invention can be applied into various organic optoelectronic devices such as organic solar cells, dye-sensitized solar cells (DSSC), or organic light emitting diodes (OLEDs). The three-dimensional ITO electrode of the present invention is capable of increasing the contact area to the active layer (or the dye molecules), enhancing the carrier collection or injection, improving the flowing efficiency and uniformity of the electric current, boosting the device conversion efficiencies, protecting the active layer from being damaged by the non-uniformity of electric current and therefore can increase the lifetime of those applied organic optoelectronic devices. In addition, some drawbacks due to the usage of tin material can be avoided because the ITO (indium-tin oxide) material used in the present invention is advanced in high stability (high resistance to acid or base), low electric resistance, and high transmittance to visible light.

According to the three-dimensional ITO electrode of the present invention, the density of the ITO nanorods formed on the conductive layer is adjustable, which may range from 1×10⁶ to 5×10¹⁰ per cm², preferably from 1×10⁸ to 1×10¹⁰ per cm², and most preferably 5×10⁹ per cm².

The three-dimensional ITO electrode of the present invention can be applied to various organic optoelectronic devices such as organic solar cells, dye-sensitized solar cells, or organic light emitting diodes (OLEDs), and preferably applied to organic solar cells. When the three-dimensional ITO electrode of the present invention is applied to an organic solar cell, the adjustable length of the ITO nanorods preferably ranges from 50 nm to 200 nm, and the adjustable diameter of the ITO nanorods preferably ranges from 30 nm to 50 nm.

According to the three-dimensional ITO electrode of the present invention, the conductive layer is preferably a transparent conductive layer, a metal layer, a conductive ceramics layer, a semiconductive layer, or a conductive polymer layer, and more preferably a transparent conductive layer, in which, the transparent conductive layer is preferably an ITO (indium tin oxide) layer, an IZO (indium zinc oxide) layer, an AZO (aluminum doped zinc oxide) layer, a GZO (gallium doped Zinc Oxide) layer, or a zinc oxide layer.

The present invention still further provides a method of fabricating a three-dimensional ITO electrode, which comprises: (A) preparing an evaporator having a reacting chamber, an evaporating source placed at the bottom of the reacting chamber, and a substrate holder facing the evaporating source and connecting to the ceiling of the reacting chamber; (B) importing a substrate having a conductive layer thereon into the chamber and holding the substrate by the substrate holder, tuning the angle between the normal direction of the substrate and the bottom of the chamber to range from 0 to 90 degrees (which means the substrate can be turned for any position opposite to the bottom of the chamber including parallel, vertical, or with some angle to the bottom of the chamber); and (C) processing oblique evaporation to form a plurality of ITO nanorods on the conductive layer of the substrate, thus the three-dimensional ITO electrode locating on the substrate is obtained. The present invention uses oblique evaporation method to form a plurality of ITO nanorods on the conductive layer of the substrate therefore the process time can be reduced, also the cost of equipment and material can be lowered. In this connection, the method of fabricating a three-dimensional ITO electrode of the present invention is advanced in industrial application for large quantities to be manufactured.

The method of fabricating a three-dimensional ITO electrode of the present invention may preferably comprise a step: providing an oxygen gas and an inert gas into the chamber when processing oblique evaporation in the step (C), in which the inert gas is preferably nitrogen gas. The flow ratio of oxygen gas versus inert gas provided into the chamber is preferably 0.5 or less, and more preferably 10⁻⁵ to 0.15. According to the method of the present invention, by introducing nitrogen gas or mixture of nitrogen gas and oxygen gas during oblique evaporation, conductive ITO nanorods can be formed on various substrates such as ITO-coated glass, semiconductive layer, etc.

According to the method of fabricating a three-dimensional ITO electrode of the present invention, the angle between the normal direction of the substrate and the bottom of the chamber is tunable in a range from 0 to 90 degrees, preferably from 5 to 85 degrees, and more preferably from 60 to 75 degrees, in which the angle should be adjusted according to the surface structure of the conductive layer.

According to the method of fabricating a three-dimensional ITO electrode of the present invention, the pressure during the oblique evaporation of step (C) preferably ranges from 10⁻⁶ to 10⁻³ torr.

According to the method of fabricating a three-dimensional ITO electrode of the present invention, the temperature during the oblique evaporation of step (C) preferably ranges from 100° C. to 450° C.

The present invention also provides an evaporator having a reacting chamber, an evaporating source placed at the bottom of the reacting chamber, and a substrate holder facing the evaporating source and connecting to the ceiling of the reacting chamber. When the substrate holder of the evaporator holds a substrate, the angle between the normal direction of the substrate and the bottom of the chamber is tunable in a range from 0 to 90 degrees.

Meanwhile, the evaporator as described above may further comprise a turntable connecting between the chamber and the substrate holder, which enables the substrate holder to rotate and change its position opposite to the bottom of the chamber (or opposite to the evaporating source).

The present invention also provides an organic solar cell, which comprises a three-dimensional ITO electrode; a metal electrode; and an active layer formed between the three-dimensional ITO electrode and the metal electrode. In the said organic solar cell, the three-dimensional ITO electrode comprises a conductive layer and a plurality of ITO nanorods formed on the conductive layer, in which the adjustable length of the ITO nanorods ranges from 50 nm to 200 nm, the adjustable diameter of the ITO nanorods ranges from 30 nm to 50 nm. With the usage of the three-dimensional ITO electrode, the organic solar cell of the present invention is capable of increasing the contact area between the ITO electrode and the active layer (or the dye molecules), enhancing the carrier collection or injection, improving the flowing efficiency and uniformity of the electric current, boosting the device conversion efficiencies, and protecting the active layer from being damaged by the non-uniformity of electric current, therefore increasing the lifetime.

According to the solar cell of the present invention, a hole-transporting layer (HTL) may be preferably comprised and formed between the three-dimensional ITO electrode and the active layer. The hole-transporting layer (HTL) is preferably made of PEDOT:PSS (Poly(3,4-ethylenedioxythiophene):poly(styrenesulfonate)), but is not limited thereto. The active layer is preferably made of P3HT:PCBM (poly(3-hexyl thiophene):[6,6]-phenyl-C61-butyric acid methyl ester) or MDMO-PPV:PCBM (poly[2-methoxy-5-(3′,7′-dimethyloctyloxy)-1,4-phenylene vinylene]:[6,6]-phenyl-C61-butyric acid methyl ester), but is not limited thereto.

According to the solar cell of the present invention, the adjustable distribution density of the ITO nanorods formed on the conductive layer preferably ranges from 1×10⁸ to 1×10¹⁰ per cm², and most preferably is 5×10⁹ per cm².

According to the solar cell of the present invention, the conductive layer of the three-dimensional ITO electrode is preferably a transparent conductive layer, a metal layer, a conductive ceramics layer, a semiconductive layer, or a conductive polymer layer, and more preferably a transparent conductive layer, in which, the transparent conductive layer is preferably an ITO (indium tin oxide) layer, an IZO (indium zinc oxide) layer, an AZO (aluminum doped zinc oxide) layer, a GZO (gallium doped Zinc Oxide) layer, or a zinc oxide layer, but is not limited thereto.

The present invention also provides a method of fabricating an organic solar cell, which comprises: (A) forming an active layer on a three-dimensional ITO electrode, in which the three-dimensional ITO electrode comprises a conductive layer and a plurality of ITO nanorods forming on the conductive layer, the adjustable length of the ITO nanorods ranges from 50 nm to 200 nm, and the adjustable diameter of the ITO nanorods ranges from 30 nm to 50 nm, (B) forming a metal electrode on the above active layer; and (C) heating the above substrate having a three-dimensional ITO electrode, an active layer, and a metal electrode for annealing. The method of fabricating an organic solar cell of the present invention is characterized in that the heating of annealing in the step (C) may improve the forming of the electric channel in the active layer, and therefore the carrier collection or injection and the electric performance of the fabricated organic solar cell can be enhanced.

According to the method of fabricating a solar cell of the present invention, the annealing temperature at step (C) is preferably 90 to 150, and the annealing duration at step (C) is preferably 10 to 150 minutes.

According to the method of fabricating a solar cell of the present invention, the active layer of step (A) is preferably made of P3HT:PCBM (poly(3-hexyl thiophene):[6,6]-phenyl-C61-butyric acid methyl ester) or MDMO-PPV:PCBM (poly[2-methoxy-5-(3′,7′-dimethyloctyloxy)-1,4-phenylene vinylene]:[6,6]-phenyl-C61-butyric acid methyl ester), but is not limited thereto.

The method of fabricating a solar cell of the present invention may further comprise a step (A1) of forming a hole-transporting layer (HTL) between the three-dimensional ITO electrode and the active layer before step (A), in which the hole-transporting layer (HTL) is preferably made of PEDOT:PSS (Poly(3,4-ethylenedioxythiophene):poly(styrenesulfonate)), but is not limited thereto.

Other objects, advantages, and novel features of the invention will become more apparent from the following detailed description when taken in conjunction with the accompanying drawings.

### BRIEF DESCRIPTION OF THE DRAWINGS

FIG. 1 is a schematic drawing showing the process steps of a fabricating a conventional solar cell;

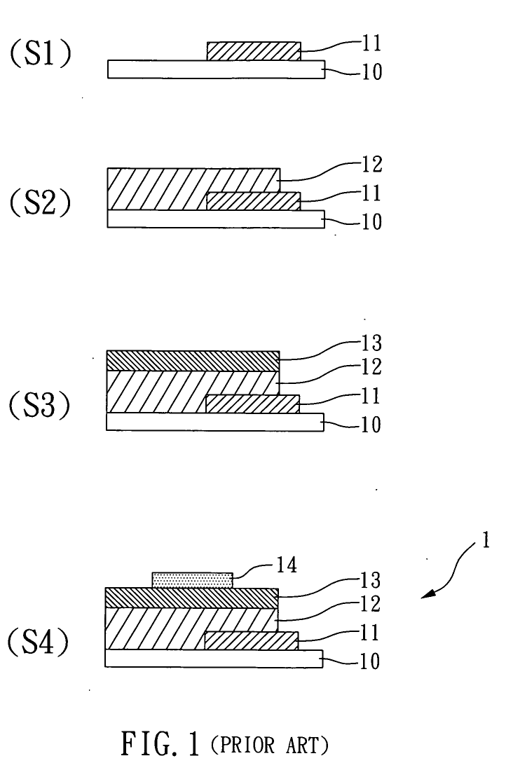

FIG. 2 is a schematic drawing of the evaporator of example 1 of the present invention;

FIG. 3 is a schematic drawing showing the angle (θ) between the normal direction of the substrate and the bottom of the chamber;

FIG. 4 is a schematic drawing of the evaporator of example 2 of the present invention;

FIG. 5 is a schematic drawing of the three-dimensional ITO electrode of example 3 of the present invention;

FIG. 6 is a schematic drawing of the organic solar cell of the example 3 of the present invention;

FIG. 7 is the current-voltage (I-V) curve testing result of the Experiment example of the present invention; and

FIG. 8 is the power conversion efficiency testing result of the Experiment example of the present invention.

### DETAILED DESCRIPTION OF THE PREFERRED EMBODIMENT

The specific examples below are to be construed as merely illustrative, and not limitative of the remainder of the disclosure in any way whatsoever. Without further elaboration, it is believed that one skilled in the art can, based on the description herein, utilize the present invention to its fullest extent. All publications cited herein are hereby incorporated by reference in their entirety.

### Example 1

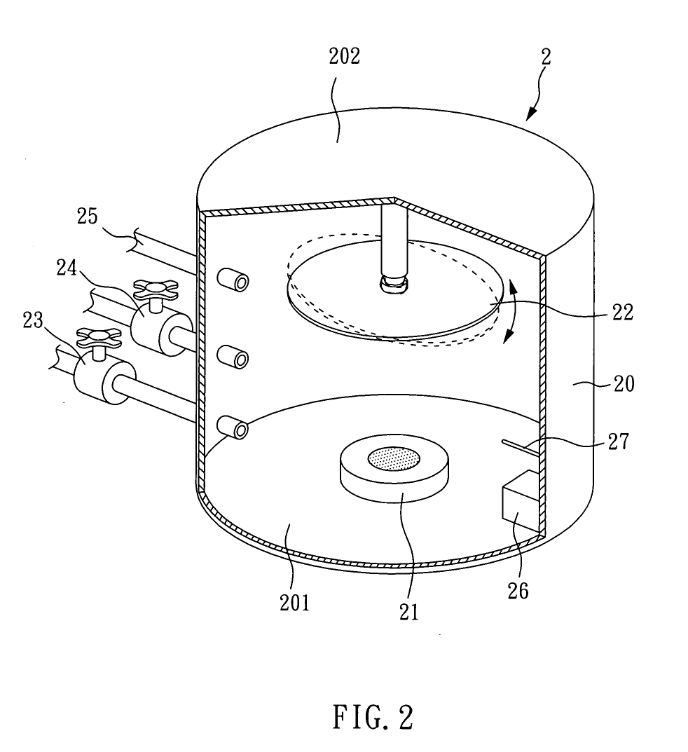

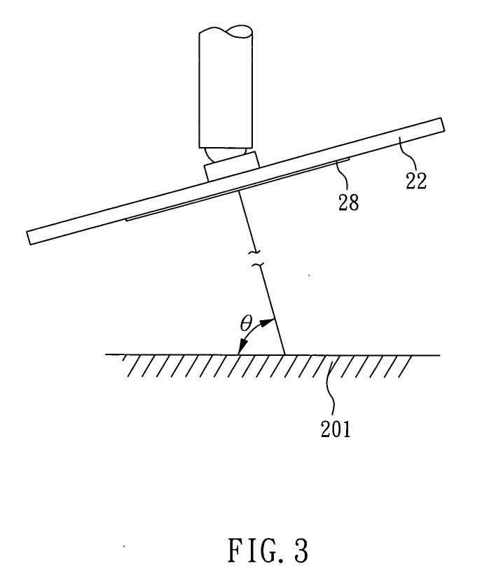

Referring to FIG. 2, there is shown an evaporator 2 of the present invention, which comprises a reacting chamber 20, an evaporating source 21 placed in the bottom 201 of the reacting chamber 20, a substrate holder 22 facing the evaporating source 21 and connecting to the ceiling 202 of the reacting chamber, a nitrogen supplying valve 23, an oxygen supplying valve 24, an exhaust tube 25, a heater 26, and a thermometer 27. With reference to FIG. 3, when a substrate 28 is held by the substrate holder 22, the angle θ between the normal direction of the substrate 28 and the bottom 201 of the chamber 20 is tunable in a range from 0 to 90 degrees, preferably from 5 to 85 degrees, more preferably from 60 to 75 degrees, in which the angle θ used in the present invention is 60 to 75 degrees.

### Example 2

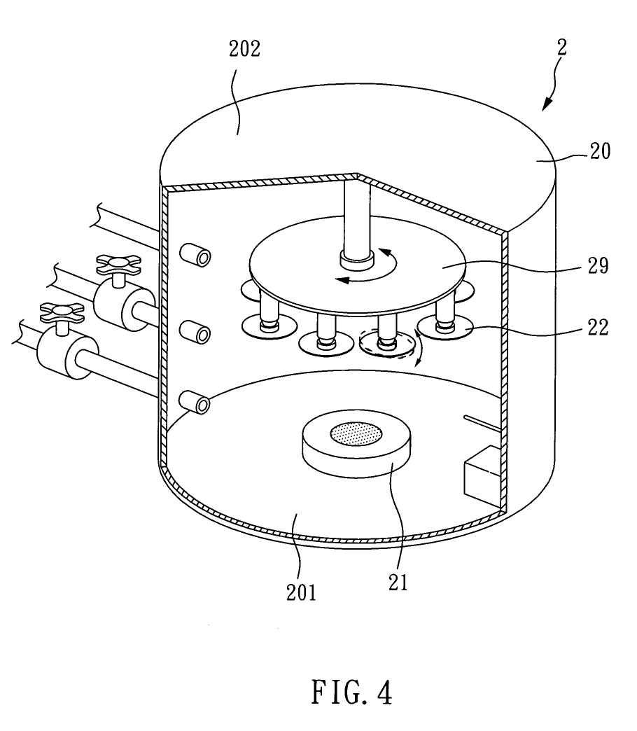

Referring to FIG. 4, there is shown another evaporator 2 of the present invention, which not only has the same features shown in Example 1, and moreover, the evaporator 2 of the present example further comprises a turntable 29 arranged between the substrate holder 22 and the ceiling 202 of the reacting chamber 20. Therefore, the relative position of the substrate holder 22 arranged at the turntable 29 via the evaporating source 21 can be adjusted by turning the turntable 29 to a desired position.

### Example 3

### Preparation of the Three-Dimensional ITO Electrode

In the present example, a three-dimensional ITO electrode is made by using the evaporator 2 of the example 1. First, an evaporator 2 as shown in FIG. 2 of the example 1 is prepared (A). With reference to FIGS. 2 and 3, a substrate 28 having a conductive layer (not shown) thereon is held by the substrate holder 22 (B). Then, the angle (θ) between the normal direction of the substrate 28 and the bottom 201 of the chamber 20 is tuned to 67 degrees. The angle (θ) is preferably adjusted according to the surface structure of the conductive layer, which is preferably in a range from 0 to 90 degrees, more preferably from 5 to 85 degrees, and most preferably from 60 to 75 degrees. Subsequently, nitrogen gas and oxygen gas are supplied into the chamber 20 by the nitrogen supplying valve 23 and oxygen supplying valve 24 respectively, the flow ratio of oxygen gas versus inert gas is controlled at 0.5 or less, preferably 0.1 or less. The total pressure of the chamber 20 should be controlled in a range between 10⁻⁶ to 10⁻³ torr, and the temperature of the chamber 20 should be controlled at 100° C. to 450° C. Oblique evaporation is then performed to form a plurality of ITO nanorods on the conductive layer of the substrate 28 (C), thus the three-dimensional ITO electrode locating on the substrate 28 is obtained.

The conductive layer formed on the substrate is preferably made of a transparent conductive material (such as ITO (indium tin oxide), IZO (indium zinc oxide), AZO (aluminum doped zinc oxide), GZO (gallium doped Zinc Oxide), or zinc oxide), metal, conductive ceramics, a semiconductive material, or a conductive polymer, and more preferably made of the transparent conductive material, but is not limited thereto. The conductive layer formed on the substrate 28 of the present example is made of ITO (indium tin oxide).

The present invention uses an oblique evaporation method to form a plurality of ITO nanorods on the conductive layer of the substrate whereby the process time can be reduced, also the cost of equipment and material can be lowered. In this connection, the method of fabricating a three-dimensional ITO electrode of the present invention is advanced in industrial application for large quantities to be manufactured.

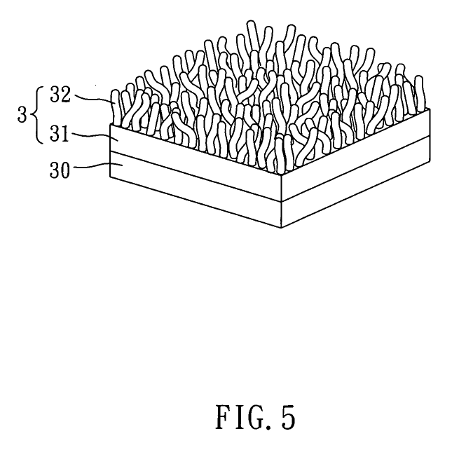

Referring to FIG. 5, there is shown schematic drawing of a three-dimensional ITO electrode 3 of the present invention, which comprises a conductive layer 31 and a plurality of ITO nanorods 32 formed on the conductive layer 31. From the SEM testing results, it can be seen that the adjustable length of the ITO nanorods ranges from 10 nm to 1500 nm, and the adjustable diameter of the ITO nanorods ranges from 10 nm to 120 nm. According to the present invention, the adjustable distribution density of the ITO nanorods formed on the conductive layer ranges from 1×10⁶ to 5×10¹⁰ per cm².

The three-dimensional ITO electrode of the present invention can be applied into various organic optoelectronic devices such as organic solar cells, dye-sensitized solar cells, or organic light emitting diodes (OLEDs). The three-dimensional ITO electrode of the present invention is capable of increasing the contact area to the active layer (or the dye molecules), improving the flowing efficiency and uniformity of the electric current, protecting the active layer from being damaged by the non-uniformity of electric current and therefore can increase the lifetime of those applied organic optoelectronic devices. When the three-dimensional ITO electrode of the present invention is applied to an organic solar cell, the length of the ITO nanorods is preferably adjusted to be in a range from 50 nm to 200 nm, and the diameter of the ITO nanorods is preferably ranged from 30 nm to 50 nm. Therefore, some drawbacks due to the usage of tin material can be avoided because the ITO (indium-tin oxide) material used in the present invention is advanced in high stability (high resistance to acid or base), low electric resistance, and high transmittance to visible light.

### Example 4-10

### Preparation of the Three-Dimensional ITO Electrodes

The same method as described in example 3 is used to fabricate the three-dimensional ITO electrodes of examples 4-10, except the angles (θ) between the normal direction of the substrate and the bottom of the chamber should be changed according to those listed in Table 1. The selection of the angle (θ) between the normal direction of the substrate and the bottom of the chamber depends upon the structure of the conductive layer formed on the substrate.

TABLE 1

| | Angle (θ) |
|---|---|
| Example 4 | 9.5 degrees |
| Example 5 | 14 degrees |
| Example 6 | 24.5 degrees |
| Example 7 | 38 degrees |
| Example 8 | 43 degrees |
| Example 9 | 77 degrees |
| Example 10 | 85 degrees |

### Example 11

### Preparation of the Three-Dimensional ITO Electrode for an Organic Solar Cell

The same method and conditions as described in example 3 are used to fabricate a three-dimensional ITO electrode for an organic solar cell, except the time for oblique evaporation should be properly adjusted. According to the obtained three-dimensional ITO electrode in the present example, the ITO nanorods have a length of about 50 nm to 200 nm, and a diameter of about 30 nm to 50 nm. The three-dimensional ITO electrode in the present example has a similar shape as shown in FIG. 5, in which the three-dimensional ITO electrode 3 comprises a conductive layer 31 and a plurality of ITO nanorods 32 formed on the conductive layer 31.

### Example 12

### Preparation of the Organic Solar Cell

A three-dimensional ITO electrode produced from example 11 is used to fabricate the organic solar cell of the present example.

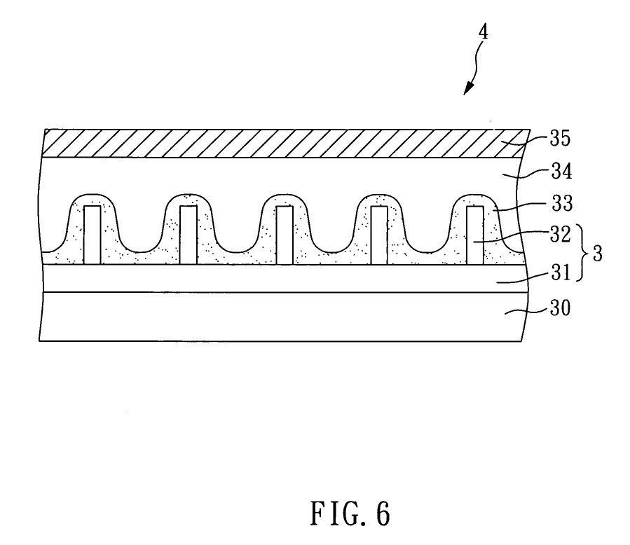

First, referring to FIG. 6, a hole-transporting layer (HTL) 33 is formed on the three-dimensional ITO electrode 3 (A1), then an active layer 34 is formed on the hole-transporting layer (HTL) 33 (A), following with an A1 electrode 35 being formed on the active layer 34 (B). Finally, the above substrate having a three-dimensional ITO electrode 3, a hole-transporting layer (HTL) 33, an active layer 34, and an A1 electrode 35 formed on the substrate 30 is annealed at 150° C. for 10 to 150 minutes (C). Therefore, the organic solar cell of the present example is obtained. In the method of the present invention, the annealing process is an important step, which enhances the forming of the electric current channel and the carrier collection or injection of the active layer of the solar cell, and as a result, the flow efficiency and uniformity of the electric current can be improved.

According to the present invention, the active layer 34 is preferably made of P3HT:PCBM (poly(3-hexyl thiophene):[6,6]-phenyl-C61-butyric acid methyl ester) or MDMO-PPV:PCBM(poly[2-methoxy-5-(3′,7′-dimethyloctyloxy)-1,4-phenylene vinylene]:[6,6]-phenyl-C61-butyric acid methyl ester), in which the active layer 34 of the present example is made of P3HT:PCBM. The hole-transporting layer (HTL) 33 of the present example is made of PEDOT:PSS (Poly(3,4-ethylenedioxythiophene):poly(styrenesulfonate)).

Referring to FIG. 6, a schematic drawing of an organic solar cell of the present example is shown, which comprises a three-dimensional ITO electrode 3, a hole-transporting layer (HTL) 33, an active layer 34, and a metal electrode 35. The active layer 34 locates between the three-dimensional ITO electrode 3 and the metal electrode 35, the hole-transporting layer (HTL) 33 locates between the three-dimensional ITO electrode 3 and the active layer 34, in which the three-dimensional ITO electrode 3 comprises a conductive layer 31 and a plurality of ITO nanorods 32 formed on the conductive layer. The adjustable length of the ITO nanorods 32 ranges from 50 nm to 200 nm, the adjustable diameter of the ITO nanorods 32 ranges from 30 nm to 50 nm, and the density of the ITO nanorods 32 formed on the conductive layer 31 is 1×10⁸ to 1×10¹⁰ per cm².

### Experiment Example

### Device Conversion Efficiency Test

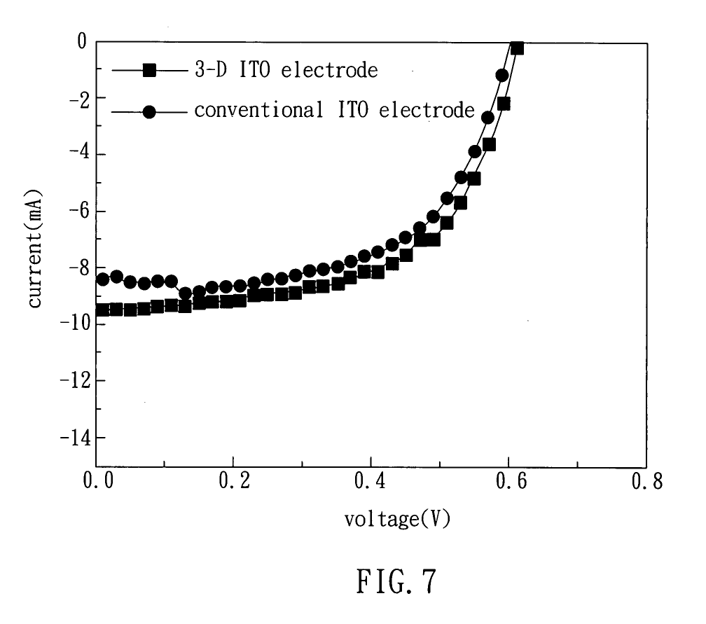

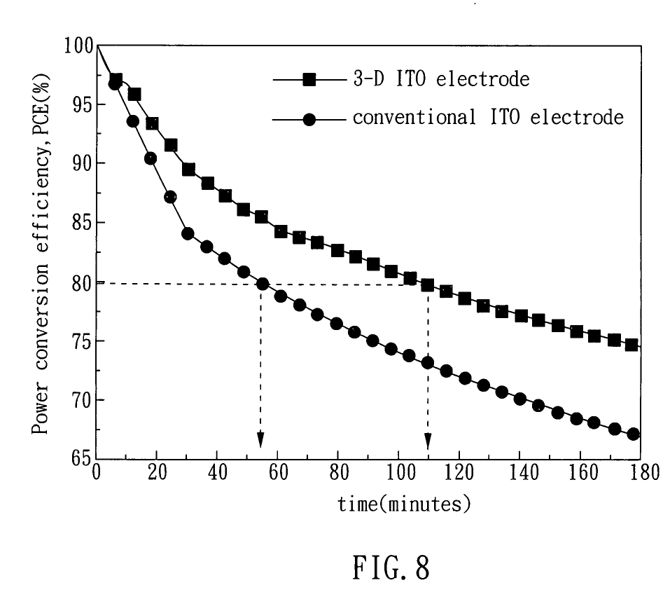

A three-dimensional ITO electrode of example 3 and a conventional layered ITO electrode are taken to test for their power conversion efficiency (PCE), and the results are as shown in FIGS. 7-8 and Table 2.

TABLE 2

| | Isc (mA) | Voc (V) | FF (%) | PCE (%) |
|---|---|---|---|---|
| Three-dimensional ITO | 9.53 | 0.61 | 58.7 | 3.41 |
| electrode of example 3 | | | | |
| Conventional layered ITO | 8.35 | 0.6 | 62.13 | 3.11 |
| electrode | | | | |

According to the results of FIGS. 7-8 and Table 2, it is shown that at the same voltage a greater electric current occurs in the three-dimensional ITO electrode of the present invention compared with that of the traditional layered ITO electrode, and moreover the power conversion efficiency (PCE) of the three-dimensional ITO electrode of the present invention is higher than that of the traditional layered ITO electrode. Therefore, it is apparent the three-dimensional ITO electrode of the present invention has a better electrical performance, which cannot be realized by the traditional ITO electrodes.

According to the organic solar cell three-dimensional ITO electrode of the present invention, the contact area between the electrode and the active layer is increased, the electric current collecting efficiency and uniformity of electric current spreading (flowing) is improved, the damage phenomenon priorly occurring from the non-uniformity of electric current can be resolved, therefore the lifetime of the applied organic solar cell can be extended.

Although the present invention has been explained in relation to its preferred embodiment, it is to be understood that many other possible modifications and variations can be made without departing from the scope of the invention as hereinafter claimed.

What is claimed is:

1. A three-dimensional ITO electrode, which comprises:
a conductive layer; and
a plurality of ITO nanorods formed on the conductive layer;
wherein the adjustable length of the ITO nanorods ranges from 10 nm to 1500 nm, the adjustable diameter of the ITO nanorods ranges from 10 nm to 120 nm, and the adjustable distribution density of the ITO nanorods formed on the conductive layer ranges from 1×10⁶ to 5×10¹⁰ per cm².

2. The three-dimensional ITO electrode as claimed in claim 1, wherein the three-dimensional ITO electrode is used in an organic solar cell, and adjustable length of the ITO nanorods ranges from 100 nm to 200 nm, the adjustable diameter of the ITO nanorods ranges from 30 nm to 50 nm.

3. The three-dimensional ITO electrode as claimed in claim 1, wherein the adjustable distribution density of the ITO nanorods formed on the conductive layer ranges from 1×10⁸ to 1×10¹⁰ per cm².

4. The three-dimensional ITO electrode as claimed in claim 1, wherein the conductive layer is a transparent conductive layer, a metal layer, a conductive ceramics layer, a semiconductive layer, or a conductive polymer layer.

5. The three-dimensional ITO electrode as claimed in claim 1, wherein the transparent conductive layer is an ITO (indium tin oxide) layer, an IZO (indium zinc oxide) layer, an AZO (aluminum doped zinc oxide) layer, a GZO (gallium doped Zinc Oxide) layer, or a zinc oxide layer.

6. A method of fabricating a three-dimensional ITO electrode, which comprises:
(A) preparing an evaporator having a reacting chamber, an evaporating source placed at the bottom of the reacting chamber, and a substrate holder facing the evaporating source and connecting to the ceiling of the reacting chamber;
(B) importing a substrate having a conductive layer thereon into the chamber and holding the substrate by the substrate holder, tuning the angle between the normal direction of the substrate and the bottom of the chamber to range from 0 to 90 degrees; and
(C) processing oblique evaporation to form a plurality of ITO nanorods on the conductive layer of the substrate, thus the three-dimensional ITO electrode locating on the substrate is obtained.

7. The method of fabricating a three-dimensional ITO electrode as claimed in claim 6, further comprising a step: providing an oxygen gas and an inert gas into the chamber when processing oblique evaporation in the step (C).

8. The method of fabricating a three-dimensional ITO electrode as claimed in claim 7, wherein the inert gas is nitrogen gas.

9. The method of fabricating a three-dimensional ITO electrode as claimed in claim 7, wherein the flow ratio of oxygen gas versus inert gas provided into the chamber is 0.5 or less.

10. The method of fabricating a three-dimensional ITO electrode as claimed in claim 6, wherein the angle between the normal direction of the substrate and the bottom of the chamber ranges from 5 to 85 degrees.

11. The method of fabricating a three-dimensional ITO electrode as claimed in claim 10, wherein the angle between the normal direction of the substrate and the bottom of the chamber ranges from 60 to 75 degrees.

12. The method of fabricating a three-dimensional ITO electrode as claimed in claim 6, wherein the pressure during the oblique evaporation of step (C) ranges from 10⁻⁶ to 10⁻³ torr.

13. The method of fabricating a three-dimensional ITO electrode as claimed in claim 6, wherein temperature during the oblique evaporation of step (C) ranges from 100° C. to 450° C.

14. An evaporator for forming a three-dimensional ITO electrode on a conductive layer forming on a substrate, which comprises:
a reacting chamber;
an evaporating source placed at the bottom of the reacting chamber; and
a substrate holder facing the evaporating source and connecting to a ceiling of the reacting chamber;
when the substrate having a conductive layer forming thereon is held by the substrate holder, the angle between the normal direction of the substrate and the bottom of the chamber is tunable in a range from 0 to 90 degrees.

15. An organic solar cell, which comprises:
a three-dimensional ITO electrode;
a metal electrode; and
an active layer forming between the three-dimensional ITO electrode and the metal electrode;
wherein the three-dimensional ITO electrode comprises a conductive layer; and a plurality of ITO nanorods formed on the conductive layer, in which the adjustable length of the ITO nanorods ranges from 50 nm to 200 nm, the adjustable diameter of the ITO nanorods ranges from 30 nm to 50 nm.

16. The organic solar cell as claimed in claim 15, further comprising a hole-transporting layer (HTL) formed between the three-dimensional ITO electrode and the active layer.

17. The organic solar cell as claimed in claim 16, wherein the hole-transporting layer is made of PEDOT:PSS (Poly(3,4-ethylenedioxythiophene):poly(styrenesulfonate)).

18. The organic solar cell as claimed in claim 15, wherein the active layer is made of P3HT:PCBM (poly(3-hexyl thiophene):[6,6]-phenyl-C61-butyric acid methyl ester) or MDMO-PPV:PCBM(poly[2-methoxy-5-(3,7-dimethyloctyloxy)-1,4-phenylene vinylene]:[6,6]-phenyl-C61-butyric acid methyl ester).

19. The organic solar cell as claimed in claim 15, wherein the adjustable distribution density of the ITO nanorods formed on the conductive layer ranges from 1×10⁸ to 1×10¹° per cm².

20. The organic solar cell as claimed in claim 15, wherein the conductive layer is a transparent conductive layer, a metal layer, a conductive ceramics layer, a semiconductive layer, or a conductive polymer layer.

21. The organic solar cell as claimed in claim 20, wherein the transparent conductive layer is an ITO (indium tin oxide) layer, an IZO (indium zinc oxide) layer, an AZO (aluminum doped zinc oxide) layer, a GZO (gallium doped Zinc Oxide) layer, or a zinc oxide layer.

22. A method of fabricating an organic solar cell, which comprises:
(A) forming an active layer on a three-dimensional ITO electrode, wherein the three-dimensional ITO electrode comprises a conductive layer and a plurality of ITO nanorods formed on the conductive layer, the adjustable length of the ITO nanorods ranges from 50 nm to 200 nm, and the adjustable diameter of the ITO nanorods ranges from 30 nm to 50 nm;
(B) forming a metal electrode on the above active layer; and
(C) heating the substrate having a three-dimensional ITO electrode, an active layer, and a metal electrode for annealing.

23. The method of fabricating an organic solar cell as claimed in claim 22, wherein the annealing temperature at step (C) is 90 to 150° C., and the annealing time is 10 to 150 minutes.

24. The method of fabricating an organic solar cell as claimed in claim 22, wherein the active layer of step (A) is made of P3HT:PCBM (poly(3-hexyl thiophene):[6,6]-phenyl-C61-butyric acid methyl ester) or MDMO-PPV:PCBM(poly[2-methoxy-5-(3′,7′-dimethyloctyloxy)-1,4-phenylene vinylene]:[6,6]-phenyl-C61-butyric acid methyl ester).

25. The method of fabricating an organic solar cell as claimed in claim 22, wherein the method further comprises a step (A1) of forming a hole-transporting layer (HTL) between the three-dimensional ITO electrode and the active layer before step (A).

26. The method of fabricating an organic solar cell as claimed in claim 25, wherein the hole-transporting layer (HTL) is made of PEDOT:PSS (Poly(3,4-ethylenedioxythiophene):poly(styrenesulfonate)).
